(19) United States
(12) Patent Application Publication
(10) Pub. No.: US 2025/0254972 A1
(43) Pub. Date: Aug. 7, 2025

(54) LOGIC CROSS-COUPLE WITH BACKSIDE INTERCONNECTS

(71) Applicant: INTERNATIONAL BUSINESS MACHINES CORPORATION, Armonk, NY (US)

(72) Inventors: Chen Zhang, Santa Clara, CA (US); Ruilong Xie, Niskayuna, NY (US); Shay Reboh, Guilderland, NY (US); James P. Mazza, Saratoga Springs, NY (US)

(21) Appl. No.: 18/432,661

(22) Filed: Feb. 5, 2024

(51) Int. Cl. H01L 27/02; H01L 27/092; H01L 29/423; H01L 29/66; H01L 29/775; H01L 29/786

(52) U.S. Cl. CPC H10D 84/038; H10D 30/014; H10D 30/43; H10D 30/6735; H10D 30/6757; H10D 64/017; H10D 64/512; H10D 84/0186; H10D 84/85; H10D 89/10

(57) ABSTRACT

A semiconductor device includes gate structures laterally disposed relative to one another across the semiconductor device. The row defines a frontside of the semiconductor device and a backside of the semiconductor device opposite the frontside. A cross-coupled circuit includes a first cross-couple connection connecting two gate structures on the frontside and a second cross-couple connection connecting two gate structures on the backside.

### BACKGROUND

The present invention generally relates to semiconductor devices and processing methods, and more particularly to area-efficient cross-couple logic circuits that employ backside interconnects.

Transistor gate pitch, referred to as contacted poly pitch (CPP), shrinks with each new generation of semiconductor device. As CPP shrinks, space between gate contacts and source/drain contacts also shrinks. As these components have less space between them, short circuit failures can begin to increase. This issue is compounded by the fact that performance of these devices needs to exceed previous generations.

Options for the placement of components, such as gate contacts, are limited especially among source/drain contacts which compete for available space. This makes gate and gate contact placement exceedingly difficult in view of decreasing sizes of source/drain regions.

Therefore, a need exists for alternate gate connection methods and wiring that preserves the electrical integrity of conductive components but provides efficient wire routing within the constraints of ever decreasing node sizes.

### SUMMARY

In accordance with an embodiment of the present invention, a semiconductor device includes a semiconductor device that includes gate structures laterally disposed relative to one another across the semiconductor device. The row defines a frontside of the semiconductor device and a backside of the semiconductor device opposite the frontside. A cross-coupled circuit includes a first cross-couple connection connecting two gate structures on the frontside and a second cross-couple connection connecting two gate structures on the backside.

In accordance with another embodiment of the present invention, a semiconductor device includes source/drain regions laterally disposed relative to one another across the semiconductor device defining a frontside of the semiconductor device and a backside of the semiconductor device opposite the frontside. Gate structures are disposed between the S/D regions. Sacrificial placeholders associated with the S/D regions are disposed toward the backside of the semiconductor device. A backside gate contact is disposed between the sacrificial placeholders to connect to a gate structure from the backside of the semiconductor device. A cross-coupled circuit includes a first cross-couple connection connecting two gate structures on the frontside and a second cross-couple connection connecting two gate structures on the backside through the backside gate contact.

In other embodiments, the cross-coupled circuit may include a multiplexer circuit, and the first cross-couple connection connects a gate of an NFET to a gate of PFET. The cross-coupled circuit may include a multiplexer circuit, and the second cross-couple connection connects a gate of an NFET to a gate of PFET. The second cross-couple connection can connect the two gate structures on the backside by a conductive path that includes middle of line gate contacts. The conductive path can include interconnects that connect the middle of line gate contacts to a metal line. The metal line can be disposed in an N-P region between active areas. The interconnects can be disposed at a middle of line level. The cross-coupled circuit can be disposed within two contacted poly pitches (CPP).

In accordance with another embodiment of the present invention, a method for fabricating a semiconductor device includes forming sacrificial placeholders in a substrate between dummy gate structures; forming source/drain regions on the sacrificial placeholders; replacing dummy material in the dummy gate structures with a replacement metal; removing the substrate to expose the sacrificial placeholders and a backside surface of the replacement metal; and forming a backside gate contact to the backside surface between two adjacent sacrificial placeholders. In other embodiments, the method includes etching the surficial placeholders to form a recess and forming a cap in the recess.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a layout view depicting cross-section lines X1, Y1 and Y2 showing corresponding cross-sectional views X1, Y1 and Y2 of a semiconductor device having a nanosheet patterned after formation of a shallow trench isolation, in accordance with an embodiment of the present invention;

FIG. 2 shows cross-sectional views X1, Y1 and Y2 of the semiconductor device having sidewall spacers formed on patterned dummy gates, in accordance with an embodiment of the present invention;

FIG. 3 shows cross-sectional views X1, Y1 and Y2 of the semiconductor device having inner spacers formed on end portions of nanosheet channel layers, in accordance with an embodiment of the present invention;

FIG. 4 shows cross-sectional views X1, Y1 and Y2 of the semiconductor device having a substrate recessed between dummy gates, in accordance with an embodiment of the present invention;

FIG. 5 shows cross-sectional views X1, Y1 and Y2 of the semiconductor device having a protective liner formed in trenches between dummy gates, in accordance with an embodiment of the present invention;

FIG. 6 shows cross-sectional views X1, Y1 and Y2 of the semiconductor device having sacrificial placeholders formed in the trenches between dummy gates, in accordance with an embodiment of the present invention;

FIG. 7 shows cross-sectional views X1, Y1 and Y2 of the semiconductor device having the protective liner removed above the sacrificial placeholders, in accordance with an embodiment of the present invention;

FIG. 8 shows cross-sectional views X1, Y1 and Y2 of the semiconductor device having source/drain regions formed, in accordance with an embodiment of the present invention;

FIG. 9 shows cross-sectional views X1, Y1 and Y2 of the semiconductor device having dummy gate material removed and replaced by a replacement metal, in accordance with an embodiment of the present invention;

FIG. 10 shows cross-sectional views X1, Y1 and Y2 of the semiconductor device having middle of line components formed, back end of line components formed and a carrier wafer bonded on a frontside of the semiconductor device, in accordance with an embodiment of the present invention;

FIG. 11 shows cross-sectional views X1, Y1 and Y2 of the semiconductor device having a substrate removed from a backside of the semiconductor device, in accordance with an embodiment of the present invention;

FIG. 12 shows cross-sectional views X1, Y1 and Y2 of the semiconductor device having a dielectric layer (e.g., a backside interlevel dielectric layer) formed on the backside of the semiconductor device, in accordance with an embodiment of the present invention;

FIG. 13 shows cross-sectional views X1, Y1 and Y2 of the semiconductor device having the sacrificial placeholders etched to form recesses, in accordance with an embodiment of the present invention;

FIG. 14 shows cross-sectional views X1, Y1 and Y2 of the semiconductor device having caps formed within the recesses in the sacrificial placeholders, in accordance with an embodiment of the present invention;

FIG. 15 shows cross-sectional views X1, Y1 and Y2 of the semiconductor device having an etch stop liner and additional dielectric material patterned to form openings for a backside gate contact, in accordance with an embodiment of the present invention;

FIG. 16 shows cross-sectional views X1, Y1 and Y2 of the semiconductor device having the etch stop liner opened and the additional dielectric material removed from between two adjacent sacrificial placeholders to form a backside gate contact trench, in accordance with an embodiment of the present invention;

FIG. 17 shows cross-sectional views X1, Y1 and Y2 of the semiconductor device having the backside gate contact formed, in accordance with an embodiment of the present invention;

FIG. 18 shows a schematic circuit diagram and a schematic layout view of a same cross-coupled multiplexer circuit, in accordance with an embodiment of the present invention; and

FIG. 19 shows a layout view of a cross-coupled multiplexer circuit having cross-coupled connection on a frontside and a backside of a semiconductor device, in accordance with an embodiment of the present invention.

### DETAILED DESCRIPTION

In accordance with embodiments of the present invention, devices and methods are described which include forming area-efficient logic circuits on a semiconductor device. In some embodiments, the logic circuits are provided within a two contacted poly pitch (CPP) region. The reduction of the layout area of the logic circuit can be achieved by employing frontside and backside interconnections. In an embodiment, a cross-coupled logic circuit employs two pitch lines (2 CPP) where gates of transistor devices in a first pitch line are cross-coupled with gates of transistors of opposite conductivity in a second adjacent pitch line. The reduction to 2 CPP can be enabled by employing backside interconnects. More specifically, one or more gate contacts are connected from a backside of the semiconductor device in addition to one or more gate contacts connected from a frontside of the semiconductor device.

In an embodiment, one gate-to-gate connection is routed on a frontside of the semiconductor device, while a second gate-to-gate connection of the cross-couple is routed on a backside of the semiconductor device. The gate-to-gate connections can be routed over active regions or other conductive components. Metal wires for the gate-to-gate connections can reside in an N-P boundary region. The N-P boundary region is a region between an N-type active (diffusion) region and a P-type active (diffusion) region. This space is under-utilized since this region is often employed for isolation between adjacent components.

Logic cross-coupled circuits can be used in many applications, e.g., in one structure, the logic cross-coupled circuit can include a multiplexer (MUX) circuit. Other sequential logic structures can also benefit from cross-coupled circuits. As a logic circuit's standard cell height scales, e.g., below 5 tracks (e.g., cell height in a cell layout), containing a logic cross-coupled circuit within a 2 CPP pitch is extremely challenging to achieve with adequate margins. A 3 CPP logic cross-coupled circuit becomes a logical alternative; however going from 2 CPP to 3 CPP can lead to a significant total logic area penalty (e.g., 7% or more).

Embodiments of the present invention, employ backside power distribution network (BSPDN) technology to provide a 2 CPP logic cross-couple solution, which can include placement of at least one of the two gate-gate connections on the backside of the semiconductor device. This results in freeing up at least one signal track on the frontside to enable the 2 CPP cross-couple construct.

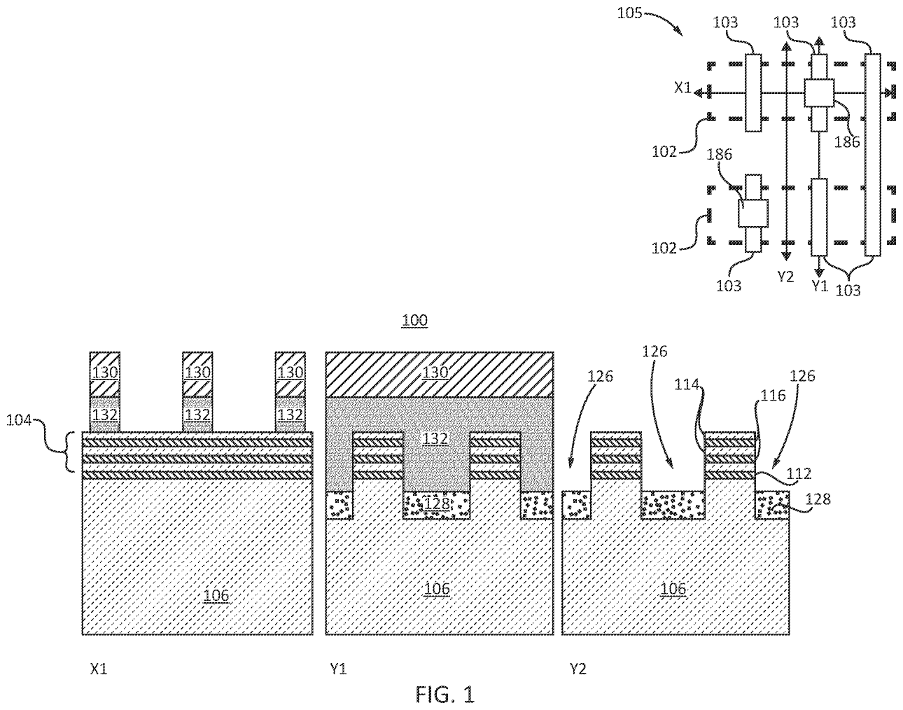

Referring now to the drawings in which like numerals represent the same or similar elements and initially to FIG. 1, devices and methods for manufacturing a semiconductor device are shown in accordance with embodiments of the present invention. The semiconductor device can include a nanosheet channel field effect transistor (FET) device, where a frontside (e.g., top) and a backside (bottom) of the device are processed. Other device structures are also contemplated.

An inset 105 shows a layout view where a section line X1 indicates a position in the layout view where cross-section X1 is taken; a section line Y1 indicates a position in the layout view where cross-section Y1 is taken; and a section line Y2 indicates a position in the layout view where cross-section Y2 is taken. Inset 105 includes gate lines 103 and active regions 102 orthogonally disposed relative to one another. Positions of backside gate contacts 186 are illustratively depicted. The backside gate contacts 186 are located on a backside of the wafer and connect to the gate lines 103. It should be noted that channels are formed at intersection regions between the between the gate lines 103 and active regions 102.

A semiconductor device or wafer 100 includes a substrate 106 that can have multiple layers on which the semiconductor device will be fabricated. The substrate 106 can include any suitable substrate structure or material, e.g., a bulk semiconductor, a semiconductor-on-insulator (SOI) substrate, etc., and preferably includes a monocrystalline semiconductor. In one example, the substrate 106 can include substrate portions separated by an etch stop layer (not shown).

Substrate 106 preferably includes silicon-containing material. Illustrative examples of Si-containing materials suitable for the substrate 106 can include, but are not limited to Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

A layer stack or stacks are applied to or formed on the substrate 106. In one embodiment, one or more nanosheet (NS) stacks 104 are applied to the substrate 106. In another embodiment, the stacks 104 can be epitaxially grown using different chemistries to form layers having different properties. In an embodiment, stack 104 includes a semiconductor layer 112 followed by a semiconductor layer 114, a semiconductor layer 116, a semiconductor layer 114, a semiconductor layer 116 and a semiconductor layer 114.

Each of semiconductor layers 112, 114 and 116 are selectively removeable relative to the others, e.g., by a selective etching process. In one embodiment, semiconductor layer 112 includes SiGe, where Ge is 55 atomic % of the compound; semiconductor layer 114 includes SiGe, where Ge is 30 atomic % of the compound, and semiconductor layer 116 includes Si. It should be understood that other materials or atomic percentages can be employed for semiconductor layers 112, 114 and 116. In other embodiments, different stack orders and numbers may be employed for semiconductor layers 112, 114 and 116.

A single or multiple nanosheets or an epitaxial grown layer stack can include the stack 104 which can be patterned to expose and etch the substrate 106. In one embodiment, a hard mask (not shown) may be formed by blanket depositing a layer of hard mask material, providing a patterned photoresist on top of the layer of hard mask material, and then etching the layer of hard mask material to provide the hard mask pattern for etching the stack 104. The patterned photoresist can be produced by applying a blanket photoresist layer to the surface of the hard mask material and exposing the photoresist layer to a pattern of radiation, and then developing the pattern into the photoresist layer utilizing resist developer. The pattern in the photoresist layer is transferred to the hard mask by an etch process.

Openings 126 are formed through stack 104 using an anisotropic etch process, such as a reactive ion etch (RIE) or an ion beam etch (IBE). Substrate 106 is further etched to form shallow trenches therein in accordance with openings 126. Shallow trench isolation (STI) 128 or STI region is formed in the etched trenches. STI 128 can be formed by depositing dielectric material, such as, e.g., SiO₂, SSiOₓN_{y}, SiCO or other suitable compounds. STI 128 can be deposited using chemical vapor deposition (CVD), although other deposition methods can be employed. The STI 128 can then be etched, e.g., by RIE, to a level below a top of the substrate 106.

A dummy gate material for dummy gates 132 is blanketed over the wafer 100 followed by a blanket deposition of a hard mask material to later form patterned hard mask 130, e.g., by using photolithographic patterning. The dummy gate material can include a polysilicon, amorphous Si or other selectively removeable material. The hard mask 130 is employed to etch the dummy gates 132.

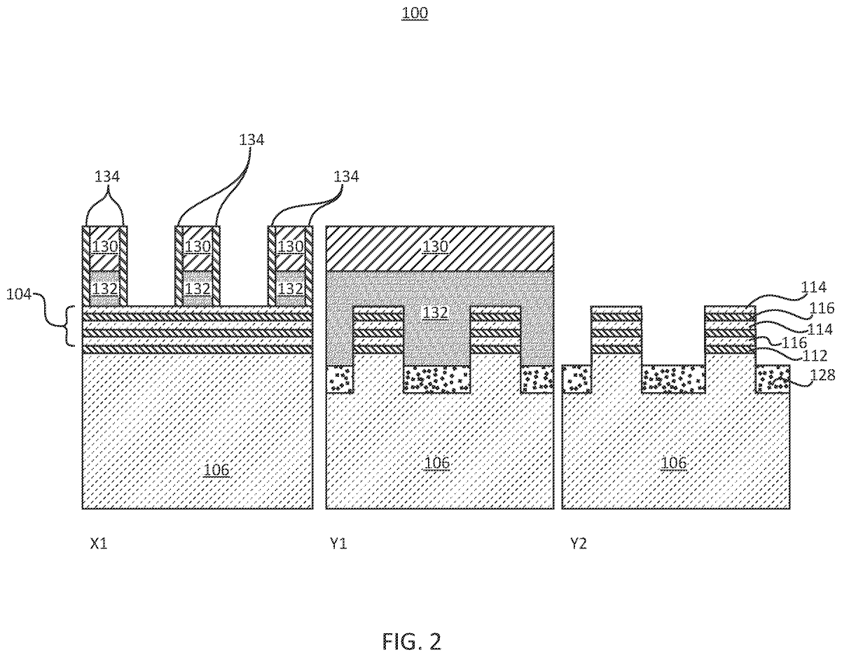

Referring to FIG. 2. a deposition process is employed to form spacers 134. Spacers 134 can include an oxide or a nitride which can be deposited conformally by a CVD process followed by a spacers etch to remove the oxide from horizontal surfaces.

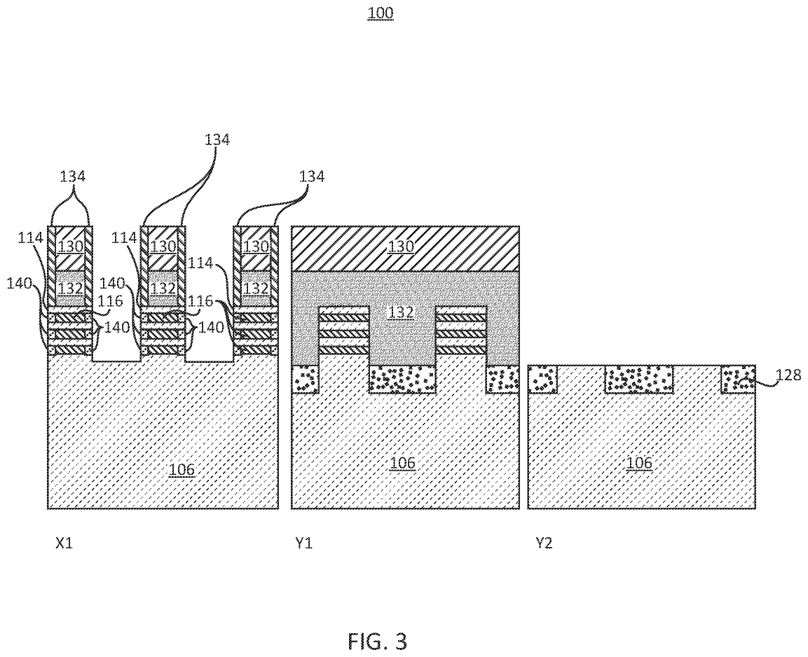

Referring to FIG. 3, the hard mask 130 and spacers 134 can be employed as an etch mask to recess the nanosheet (e.g., stack 104) to expose substrate 106 in section X1. Regions of the nanosheet below the hard mask 130 and spacers 134 are patterned for further processing while the nanosheet (e.g., stack 104) is completely removed in other regions, e.g., section Y2. Inner spacers 140 are formed and include a dielectric material. In one embodiment, the inner spacers 140 are formed using exposed portions of the semiconductor layer 116, which undergo a Ge condensation process to form a dielectric oxide (SiO₂) at the exposed portions by a thermal oxidation process. The oxidation process converts SiGe to the dielectric material and condenses out Ge.

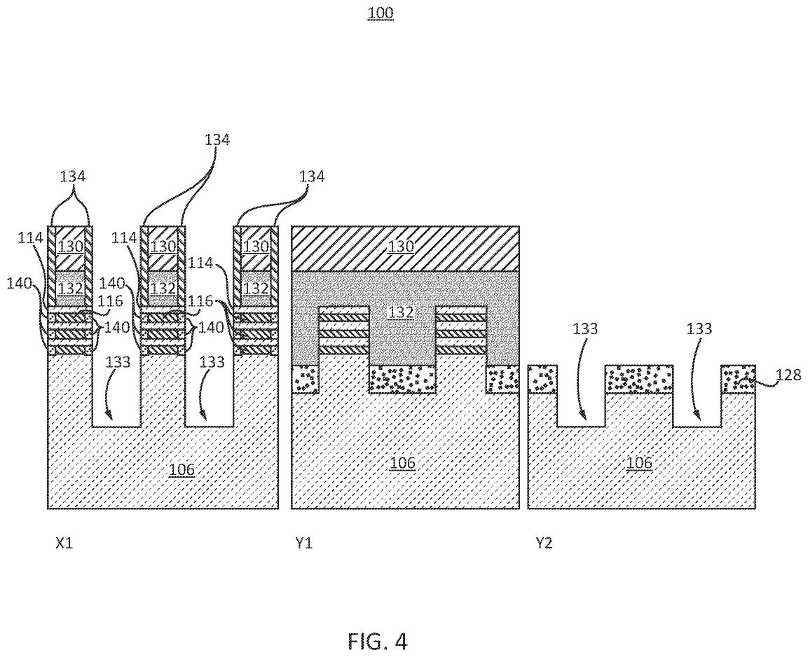

Referring to FIG. 4, the hard mask 130 and spacers 134 can be employed as an etch mask to recess the substrate 106. The substrate 106 is recessed to form trenches 133, e.g., by RIE.

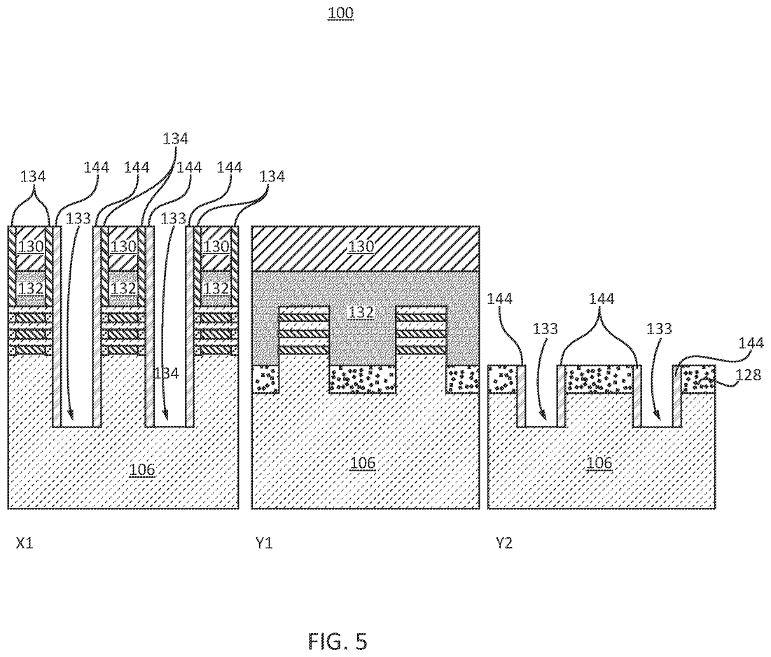

Referring to FIG. 5, a protective liner 144 is formed along sidewalls down to a bottom of trenches 133. Protective liner 144 can provide channel edge protection for later-formed channels. A conformal deposition of material can be employed for the protective liner 144. The protective liner can include, e.g., SiN. The protective liner 144 can be removed from horizontal surfaces by a selective etch, e.g., RIE.

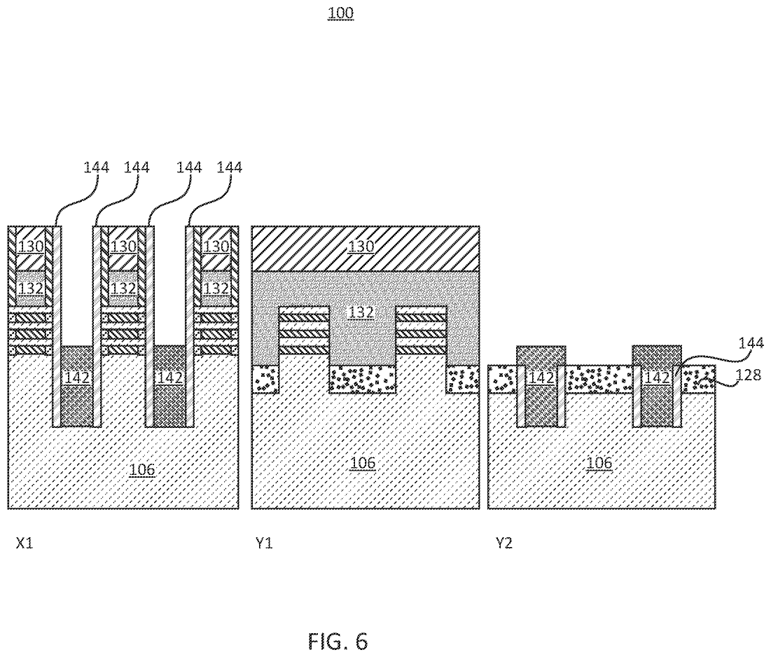

Referring to FIG. 6, within the trenches 133 recessed into the substrate 106, sacrificial placeholders 142 are formed. The sacrificial placeholders 142 can be epitaxially grown in the trenches of substrate 106. The sacrificial placeholders 142 can include SiGe or other epitaxial grown material that can be selectively removed relative to the substate 106, as needed.

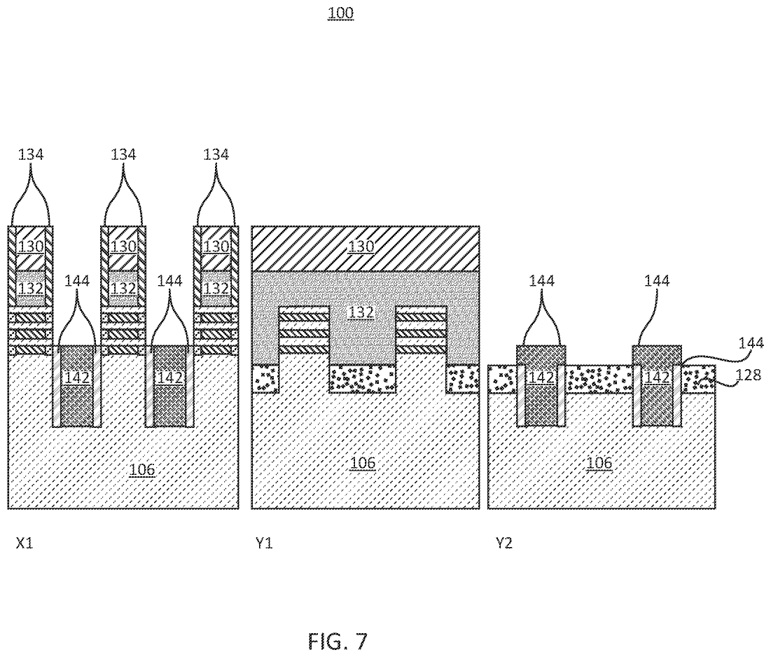

Referring to FIG. 7, the protective liner 144 is etched back and removed from the spacers 134. The protective liner 144 can be removed by a selective etch including a dry or wet etch to remove the protective line done to the sacrificial placeholders 142.

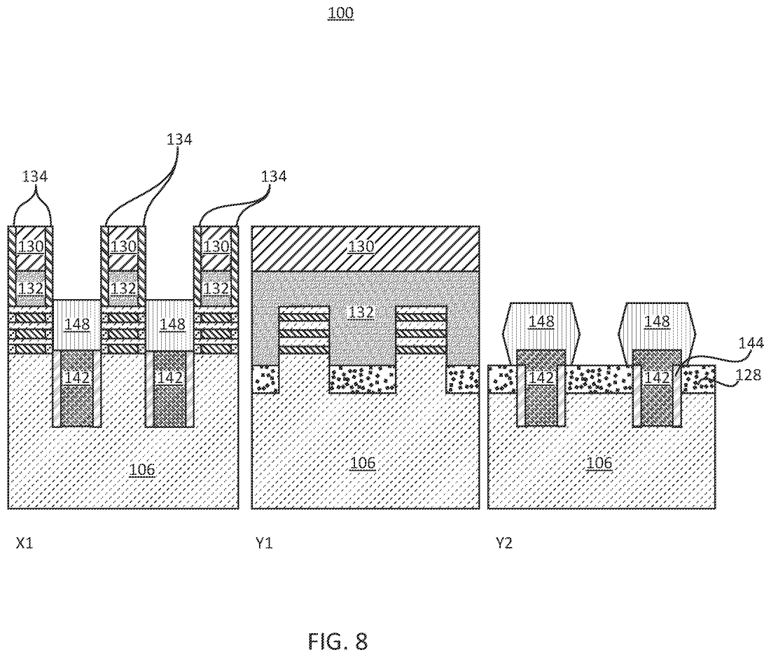

Referring to FIG. 8, an epitaxial growth process is performed to form source/drain (S/D) regions 148. S/D regions 148 can include Si or SiGe and include faceted surfaces when epitaxial growth is not confined. In one embodiment, the S/D regions 148 can be designated as P-type or N-type devices. The P-type and N-type devices can have material selected for the S/D regions 148. For example, if the S/D regions 148 include N-type devices than the S/D regions 148 can include Si. In another example, if the S/D regions 148 include P-type devices than the S/D regions 148 can include SiGe.

The S/D regions 148 can be appropriately doped during formation by epitaxial growth. For example, the S/D regions 148 can be doped by introducing p dopants (e.g., B, Ga, etc.) during epitaxial formation. Similarly, the S/D regions 148 can be doped by introducing n dopants (e.g., P, As, etc.) during epitaxial formation. In other embodiments, P-type and N-type devices can be formed adjacent to one another. Processing would include forming one device type and then the other device type by employing block masks to protect each device during processing of the other.

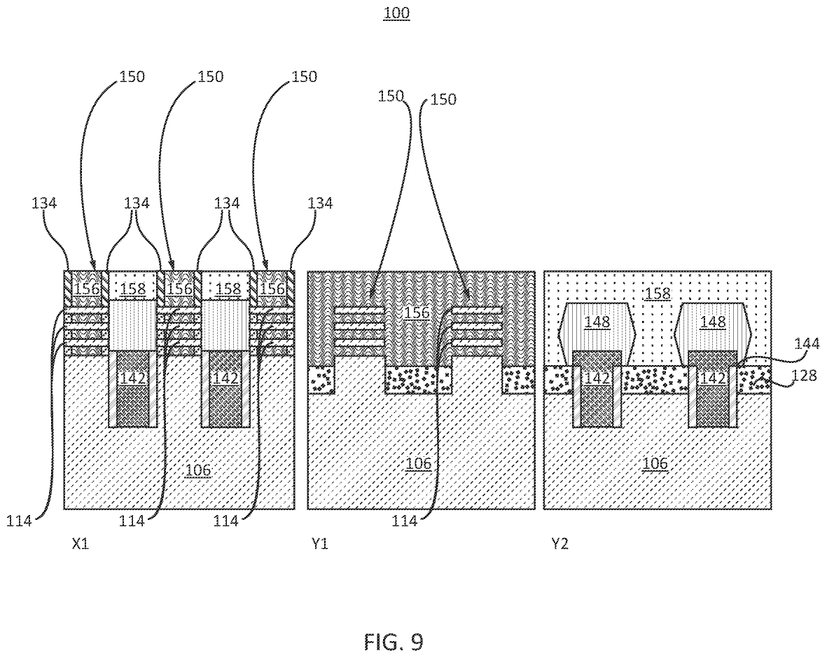

Referring to FIG. 9, a dielectric layer 158, such as, e.g., an interlevel dielectric layer (ILD) can be formed and can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, a-C: H. The dielectric layer 158 can be deposited using chemical vapor deposition (CVD), although other deposition methods can be employed.

S/D regions 148 are laterally disposed relative to one another in a row. Regions between adjacent S/D regions 148 include gate structures 150. The gate structures 150 can have device channels formed from semiconductor layers 114 (from nanosheet stack 104) passing therethrough. Other device architectures are also contemplated and the gate structures and the device channels can take other forms.

The gate structures 150 are formed by removing the hard mask 130 and the dummy material for dummy gates 132. The gate structures 150 include gate dielectric (not shown) formed in contact with semiconductor layers 114 which form the device channels, in this illustrative example. A gate electrode or gate metal 156 is deposited to replace the dummy gate material. The gate structures 150 can include Replacement Metal Gate (RMG) structures. The gate electrode or gate metal 156 is also electrically isolated by spacers 134 and inner spacers 140. The dielectric layer 158 and gate metal 156 may be planarized, e.g., by chemical mechanical polishing (CMP).

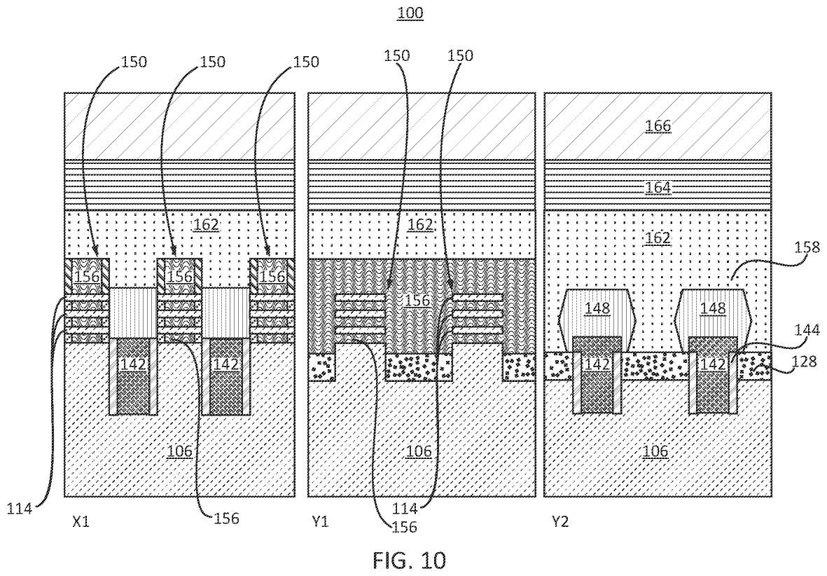

Referring to FIG. 10, middle of the line (MOL) contacts (not shown) can be formed to make connections with the S/D regions 148 and gate structures 150 from a top side of the device or wafer 100. Additional dielectric material or dielectric layer 162 can be deposited to increase a thickness of the dielectric layer 158. Contact openings (not shown) can be formed in and through the dielectric layer 162 and the dielectric layer 158. In an embodiment, a silicide liner (not shown), such as Ti, Ni, NiPt can be deposited in the contact openings for the S/D region contacts, then a diffusion barrier (not shown) can be formed in contact openings prior to a conductive fill for the formation of MOL contacts (e.g., frontside MOL contacts to S/D regions 148 and frontside MOL contacts to gate structures 150. The diffusion barrier can include, e.g., TiN, TaN, or similar materials. The MOL contacts can include materials, such as, e.g., Cu, Ru, Mo, Rh, W, Ir, and alloys or combinations of these and other conductive materials.

A back end of the line (BEOL) layer 164, which can include metal structures and dielectric layers, completes a top region and provides electrical access to earlier formed conductive structures, such as MOL contacts. A carrier wafer 166 can be bonded to the BEOL layer 164. The carrier wafer 166 provides support and transportability to the wafer 100 for further processing which can include flipping the wafer 100 and removing portions of a bottom or backside of the device.

To continue processing, the wafer 100 can be flipped to process features on the bottom or backside of the device. However, for clarity and consistency, the device will be shown in the FIGS. in a same orientation as previously described with continued and consistent reference to bottom/top.

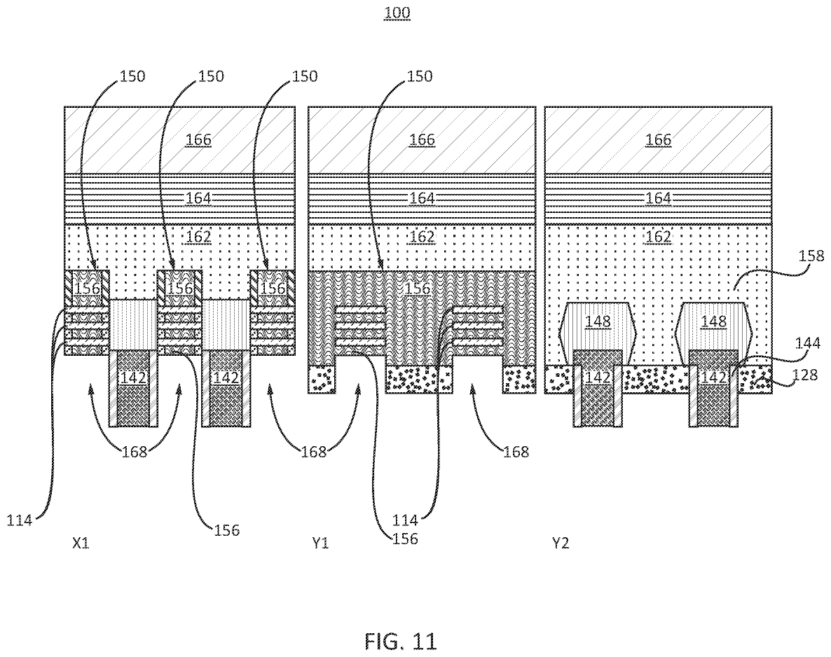

Referring to FIG. 11, the substrate 106 is removed from the backside of the device. In one embodiment, the substrate 106 can be removed by an etch process. The substrate 106 can be etched back by, e.g., a wet etch process that selectively removes the material relative to the sacrificial placeholders 142, STI 128 and gate metal 156. The gate metal 156 is exposed from the backside of the wafer 100 in communication with trenches 168, which are formed by the removal of the substrate 106.

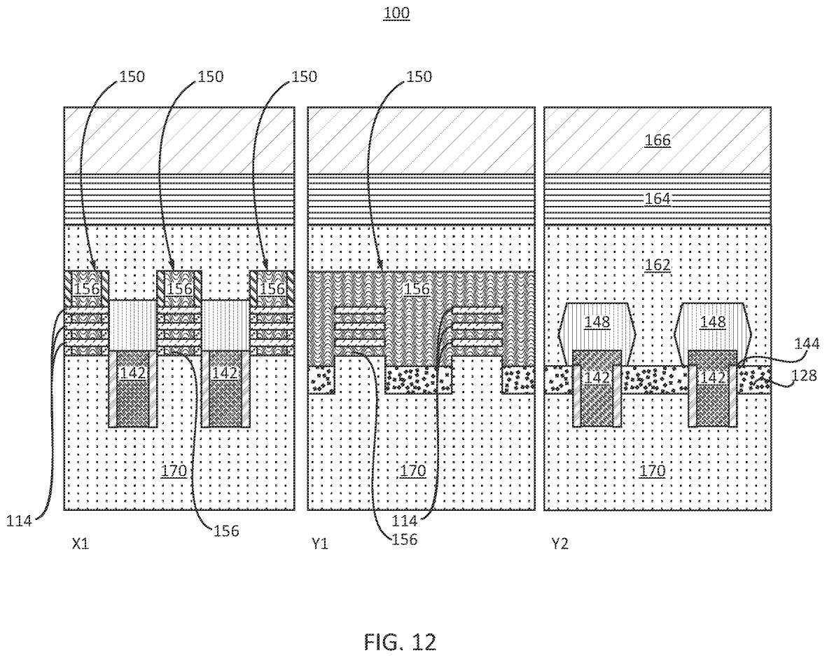

Referring to FIG. 12, a dielectric layer 170 (e.g., a backside interlevel dielectric layer (BILD)) is formed over the sacrificial placeholders 142, STI 128 and exposed gate metal 156. The dielectric layer 170 can include similar materials and formation processes as dielectric layers 158 and 162.

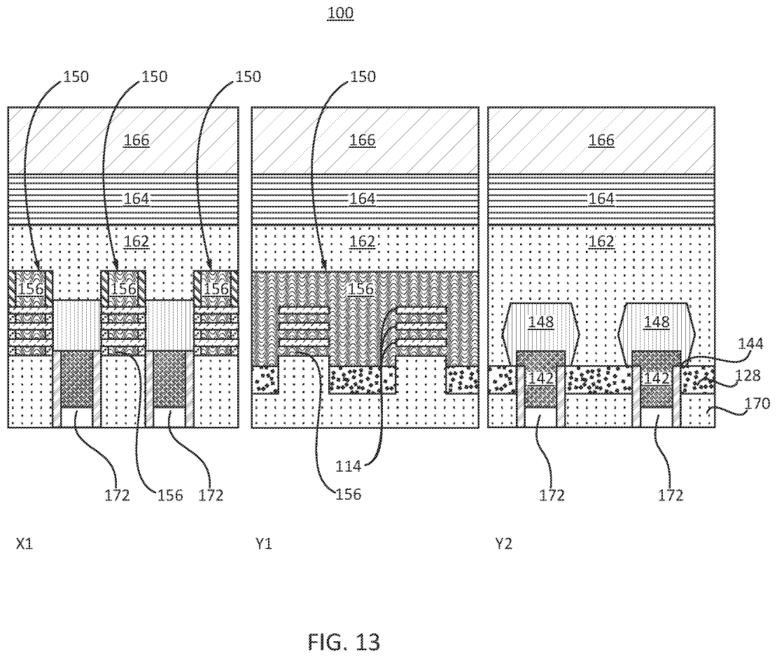

Referring to FIG. 13, the dielectric layer 170 may be planarized, e.g., by CMP, to expose a surface of the sacrificial placeholders 142. The exposed surfaces of the sacrificial placeholders 142 are recessed by a selective etch process. The selective etch process can include a wet or dry etch that removes material of the sacrificial placeholders 142 selective to the dielectric layer 170 and the protective liner 144. The selective etch process etches the sacrificial placeholders 142 to form recesses 172.

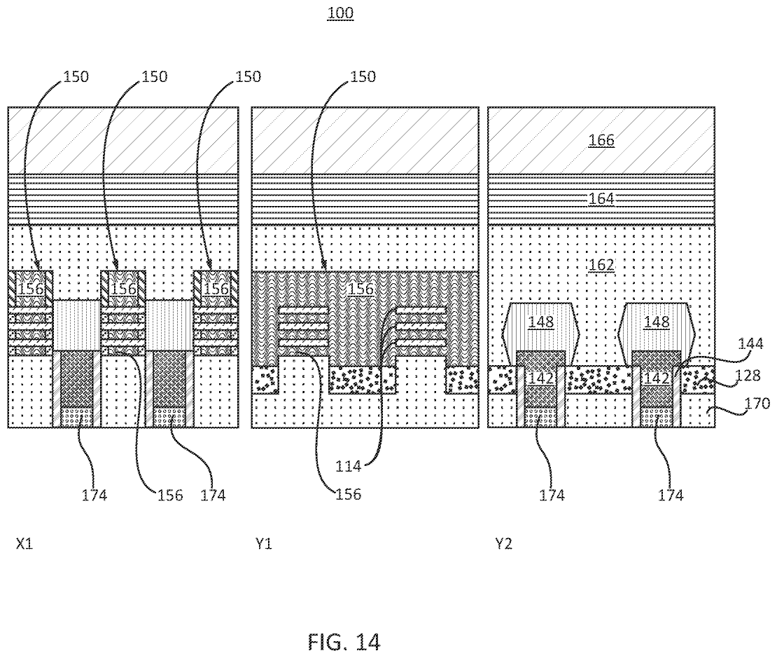

Referring to FIG. 14, a capping material is deposited over the backside of the wafer 100 to fill in the recesses 172 (FIG. 13). A planarization process, such as, e.g., CMP is performed to remove the capping material from the backside surface and form caps 174 in the recesses 172. The cap can include a high dielectric constant material such as Al₂O₃, HfO₂ or other suitable dielectric materials. The caps 174 along with protective liner 144 provide a dielectric barrier around the sacrificial placeholders 142 to reduce the risk of formation of a current leakage path through the sacrificial placeholders 142.

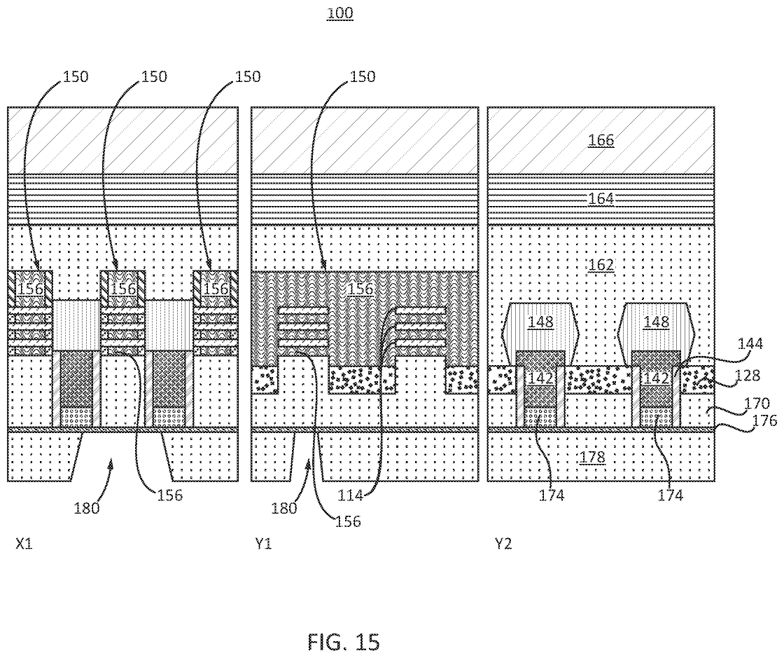

Referring to FIG. 15, an etch stop liner 176 is deposited on the backside of the wafer 100. The etch stop liner 176 can be deposited using CVD, plasma enhanced CVD (PECVD), atomic layer deposition (ALD) although other deposition methods can be employed. The etch stop liner 176 can include a dielectric material, such as, e.g., silicon nitride.

A dielectric layer 178 can be deposited on the etch stop liner 176. The dielectric layer 178 can include a same material as dielectric layer 170, although a different dielectric material can be employed. The dielectric layer 170 can be planarized, e.g., by CMP to remove access material from a free surface of the device.

A mask material (not shown) is deposited or spun onto the backside of the wafer 100. In one embodiment, the mask material includes a hard mask material that can be patterned using photolithography, e.g., using a photoresist (not shown). In some embodiments, an anti-reflective coating (ARC) layer (not shown) may be formed prior to forming the photoresist, which can be formed on the ARC layer. The layer of photoresist can be imaged with an image pattern and developed to form an etch mask. The dielectric layer 178 can be etched in accordance with the etch mask to open up trenches or openings 180 at selected locations where access to gate structures 150 is needed for backside gate contacts. Here, openings 180 are formed to span over portions of adjacent over sacrificial placeholders 142 to enable a self-aligned etch to access gate metal 156 by using the sacrificial placeholders 142 as an etch mask in next steps.

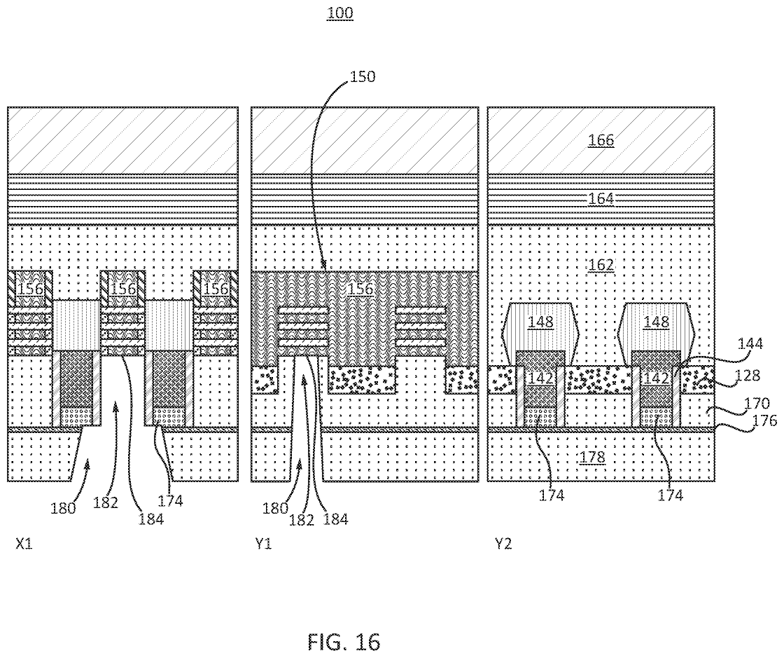

Referring to FIG. 16, a punchthrough etch of the etch stop liner 176 is performed to access the material of the dielectric layer 170 through the openings 180. A selective etch process is then performed to expand the openings 180 to form trenches 182 that reach a surface 184 of the gate metal 156. The selective etch process can include an anisotropic etch, e.g., a reactive ion etch (RIE) or ion beam etch (IBE). The anisotropic etch, such as a plasma dry etch, is self-aligned in view X1, using the caps 174 of the sacrificial placeholders 142 as an etch mask. The anisotropic etch is selective to not etch materials such as the caps 174, the protective liner 144, and the gate metal 156. The etch process is self-aligned once the dielectric layer 178 and the etch stop liner 176 are opened up to expose the caps 174 of the sacrificial placeholders 142. Opening 180 includes a widened shape to permit the trench 182 to be more easily filled.

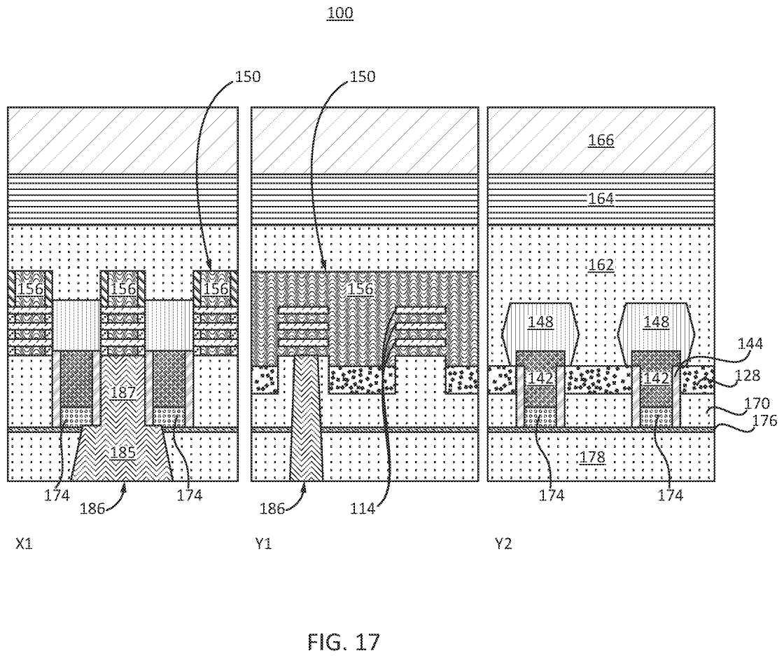

Referring to FIG. 17, a diffusion barrier can optionally be deposited in the openings 180 and trenches 182 prior to a conductive fill. The diffusion barrier can include, e.g., TiN, TaN, or similar materials. A conductive fill is performed to fill the openings 180 and trenches 182. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill can be planarized, e.g., by CMP, to remove excess material of the conductive fill and to form backside gate contact 186 to make connections with gate metal 156 of gate structure 150 from a bottom side of the wafer 100.

The backside gate contact 186 includes a first portion 185 that is relatively wider than a second portion 187. Said differently, a lateral dimension of the first portion 185 is greater than a lateral dimension of the second portion 187. In an embodiment, the first portion 185 is wider than the second portion 187 between the two adjacent sacrificial placeholders 142.

Processing continues with the formation of a backside power distribution network (BSPDN) formed on the dielectric layer 178 and the backside gate contact 186. The BSPDN can include metal structures and dielectric layers to complete the bottom side of the device and provide electrical access to the devices formed. The BSPDN connects to the backside gate contacts 186.

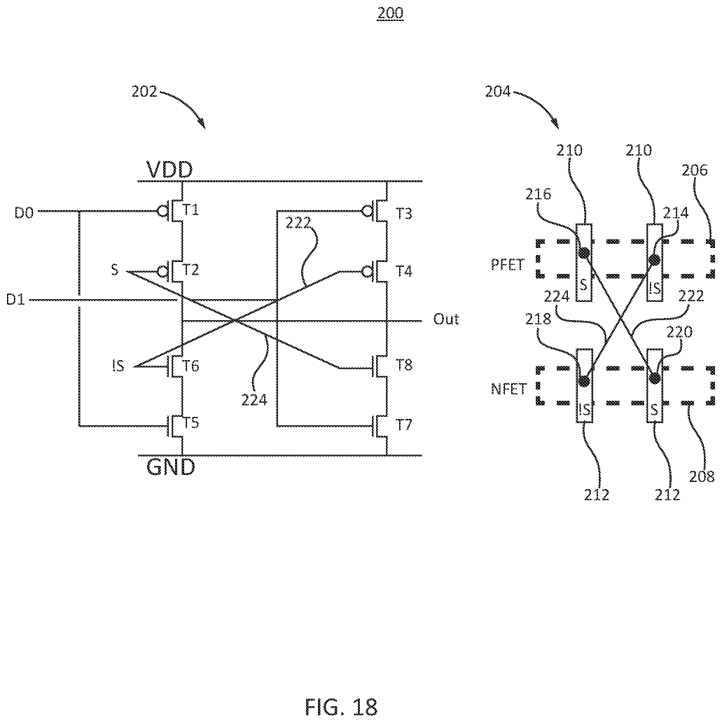

Referring to FIG. 18, a schematic diagram 202 and a layout view 204 show a cross-coupled transistor circuit 200 in accordance with embodiments of the present invention. Circuit 200 includes p-type field effect transistors (PFETs) T1-T4 and N-type field effect transistors (NFETs) T5-T8. PFETs T1-T4 are associated with active region 206 while NFETs T5-T8 are associated with active region 208. Gates 210 and 212 are labeled in the layout view 204 as NFET gates 210 and PFET gates 212. Gate contacts 214, 216, 218 and 220 are depicted in the layout view 204. Inputs to the gate contacts include signal S to gate contacts 216 and 220 while signal !S, which is an inverted signal of S, is input to gate contacts 214 and 218. Power rails are provided as VDD and GND. VDD is positive supply voltage, and GND is ground) or can be VSS (negative supply voltage).

Circuit 200 provides a 2:1 multiplexing circuit. It should be understood that other circuits, e.g., demultiplexing, etc. and larger multiplexing circuits can also be employed in accordance with embodiments of the present invention. Here, input data D0 and D1 are multiplexed and output through output line Out.

In an embodiment, the shifting of one or more pairs of gate contacts 214/218 or 216/220 to a backside of the wafer or semiconductor device enables a two contacted poly pitch (CPP) circuit (circuit 200) to be realized instead of a circuit spanning 3 or more CPP. By reducing the gate contact pitch (CPP) a smaller layout is provided for circuit 200, e.g., with an area savings of at least 7%. In an embodiment, a pair of gate contacts 214/218 and a corresponding interconnect 222 are disposed on a backside of the wafer or device, while the other pair of gate contacts 216/220 and a corresponding interconnect 224 are disposed on a frontside of the wafer or device.

In another embodiment, the pair of gate contacts 216/220 and a corresponding interconnect 224 are disposed on a backside of the wafer or device, while the pair of gate contacts 214/218 and the corresponding interconnect 222 are disposed on a frontside of the wafer or device. In another embodiment, both pairs of gate contacts 214/218 and 216/220 and their corresponding interconnects 222 and 224 are disposed on the backside of the wafer or device. By utilizing available backside real estate, area penalties for logic circuits, e.g., a multiplexing circuit can be reduced.

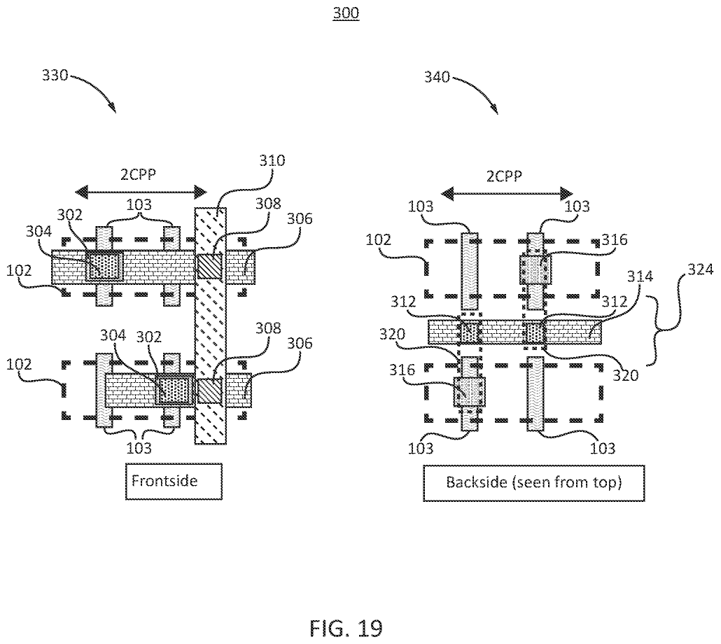

Referring to FIG. 19, a device layout 300 shows the cross-coupled circuit in the layout view 204 of FIG. 18 in greater detail in accordance with an embodiment of the present invention. Device layout 300 depicts a frontside view 330 and a backside view 340 taken from a from a top down perspective, e.g., looking through the device from the frontside. The features shown depict positions of various elements. The various elements are shown without being hidden by other elements that are stacked over the elements in order to be able to view the elements' relative location.

Active regions 102 are shown as dashed lines to be able to view the metal structures in the frontside view 330 and the backside view 340. Gate lines 103 are depicted in a transverse orientation relative to the active regions 102.

At the frontside, MOL frontside gate contacts 302 connect to the gate lines 103 and further connect to vias 304 (e.g., V0 vias) thereon. Metal lines 306 (e.g., M1) connect to the vias 304 and therefore the gate lines 103 through the MOL gate contacts 302. Vias 308 connect the metal lines (M1) 306 to metal line (e.g., M2). Two frontside gate lines 103 are therefore connected to form a first cross-coupled connection from the MOL gate contact 302, to the via 304, to metal line 306, to via 308, to metal line 310, to via 308, to metal line 306, to via 304, to the other MOL gate contact 302 on the frontside.

At the backside, MOL backside gate contacts 316 connect to the gate lines 103 that were not contacted to on the frontside. The MOL backside gate contacts 316 further connect to interconnects 320 which are present in the MOL layer or level. The interconnects 320 further connect to backside vias 312, which in turn, connect to backside metal line 314 (e.g., backside M1).

Two backside gate lines 103 are therefore connected to form a second cross-coupled connection from the MOL gate contact 316, to the interconnect 320, to the via 312, to metal line 314, to via 312, to the other interconnect 320, to the other MOL gate contact 316 on the backside.

In accordance with embodiments of the present invention, a cross-coupled circuit is realized having a first cross-coupled connection between gates on a frontside of the device and a second cross-coupled connection between gates on a backside of the device. As a result, the circuit shown in device layout 300 can be contained within a 2 CPP region. With a 2 CPP region, layout area is reduced for the cross-coupled circuit shown in device layout 300.

In an embodiment, the cross-coupled circuit shown in device layout 300 employs two pitch lines (2 CPP) (longitudinally along gate lines 103) where gates of transistor devices in a first pitch line are cross-coupled with gates of transistors of opposite conductivity in a second adjacent pitch line by employing backside interconnects or interconnects 320. More specifically, one or more gate contacts are connected from a backside of the semiconductor device to one or more gate contacts connected from a frontside of the semiconductor device.

In an embodiment, the cross-coupled circuit shown in device layout 300 can include a multiplexer circuit. In other embodiments, other circuits with cross-coupled interconnects can be realized in accordance with embodiments of the present invention.

Further, metal line 314 for the gate-to-gate connections reside in an N-P boundary region 324 (between active region 102). The N-P boundary region 324 is a region between an N-type active (diffusion) region and a P-type active (diffusion) region. In other embodiments, the metal line 314 can be located in a boundary region between any two active regions (e.g., P-P, N-N). By utilizing this space, area penalty is further reduced.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor—or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom,” “backside,” “frontside” and the like, can be used herein for ease of description to describe one element's or feature's relationship to another element(s) or feature(s) as illustrated in the FIGS. 1t will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
gate structures laterally disposed relative to one another across the semiconductor device defining a frontside of the semiconductor device and a backside of the semiconductor device opposite the frontside; and
a cross-coupled circuit including:
a first cross-couple connection connecting two gate structures on the frontside; and
a second cross-couple connection connecting two gate structures on the backside.

2. The semiconductor device as recited in claim 1, wherein the cross-coupled circuit includes a multiplexer circuit and the first cross-couple connection connects a gate of an NFET to a gate of PFET.

3. The semiconductor device as recited in claim 1, wherein the cross-coupled circuit includes a multiplexer circuit and the second cross-couple connection connects a gate of an NFET to a gate of PFET.

4. The semiconductor device as recited in claim 1, wherein the second cross-couple connection connects the two gate structures on the backside by a conductive path that includes middle of line gate contacts.

5. The semiconductor device as recited in claim 4, wherein the conductive path includes interconnects that connect the middle of line gate contacts to a metal line.

6. The semiconductor device as recited in claim 5, wherein the metal line is disposed in an N-P region between active areas.

7. The semiconductor device as recited in claim 5, wherein the interconnects are disposed at a middle of line level.

8. The semiconductor device as recited in claim 1, wherein the cross-coupled circuit is disposed within two contacted poly pitches (CPP).

9. A semiconductor device, comprising:
source/drain (S/D) regions laterally disposed relative to one another across the semiconductor device defining a frontside of the semiconductor device and a backside of the semiconductor device opposite the frontside;
gate structures disposed between the S/D regions;
sacrificial placeholders associated with the S/D regions and disposed toward the backside of the semiconductor device;
a backside gate contact disposed between the sacrificial placeholders to connect to a gate structure from the backside of the semiconductor device; and
a cross-coupled circuit including:
a first cross-couple connection connecting two gate structures on the frontside; and
a second cross-couple connection connecting two gate structures on the backside through the backside gate contact.

10. The semiconductor device as recited in claim 9, wherein the cross-coupled circuit includes a multiplexer circuit and the first cross-couple connection connects a gate of an NFET to a gate of PFET.

11. The semiconductor device as recited in claim 9, wherein the cross-coupled circuit includes a multiplexer circuit and the second cross-couple connection connects a gate of an NFET to a gate of PFET.

12. The semiconductor device as recited in claim 9, wherein the second cross-couple connection connects the two gate structures on the backside by a conductive path that includes two backside gate contacts.

13. The semiconductor device as recited in claim 12, wherein the conductive path includes interconnects that connect the two backside gate contacts to a metal line.

14. The semiconductor device as recited in claim 13, wherein the metal line is disposed in an N-P region between active areas.

15. The semiconductor device as recited in claim 13, wherein the interconnects are disposed at a middle of line level.

16. The semiconductor device as recited in claim 9, wherein the cross-coupled circuit is disposed within two contacted poly pitches (CPP).

17. The semiconductor device as recited in claim 9, wherein the sacrificial placeholders include caps.

18. The semiconductor device as recited in claim 17, wherein the backside gate contact includes a narrower portion between the sacrificial placeholders and a wider portion on the caps.

19. A method for fabricating a semiconductor device, comprising:
forming sacrificial placeholders in a substrate between dummy gate structures;
forming source/drain regions on the sacrificial placeholders;
replacing dummy material in the dummy gate structures with a replacement metal;
removing the substrate to expose the sacrificial placeholders and a backside surface of the replacement metal; and
forming a backside gate contact to the backside surface between two adjacent sacrificial placeholders.

20. The method as recited in claim 19, further comprising:
etching the sacrificial placeholders to form a recess; and
forming a cap in the recess.
